(19) United States
(12) Patent Application Publication
(10) Pub. No.: US 2013/0108967 A1
(43) Pub. Date: May 2, 2013

(54) METHOD FOR FORMING CURED FILM

(71) Applicants: Makoto Horii, Tokyo (JP); Yuma Tanaka, Tokyo (JP)

(72) Inventors: Makoto Horii, Tokyo (JP); Yuma Tanaka, Tokyo (JP)

(73) Assignee: SUMITOMO BAKELITE CO., LTD., Tokyo (JP)

(21) Appl. No.: 13/809,096

(22) PCT Filed: Jul. 5, 2011
(86) PCT No.: PCT/JP2011/003822

§ 371 Date: Jan. 8, 2013

(30) Foreign Application Priority Data
Jul. 9, 2010 (JP) 2010-156274

(51) Int. Cl. G03F 7/20

(52) U.S. Cl. CPC G03F 7/20
USPC 430/326

(57) ABSTRACT

The present invention provides a method for forming a cured film of a positive type photosensitive polymer composition over a support, including: a coating step for coating the aforementioned support with the aforementioned positive type photosensitive polymer composition; an exposure step for selectively irradiating the aforementioned positive type photosensitive polymer composition with a chemical ray to achieve an exposure; a developing step for developing an exposed section of the aforementioned positive type photosensitive polymer composition with an alkaline developer solution; a rinsing process for rinsing the aforementioned developer solution off with a rinsing solution and removing the exposed section of the aforementioned positive type photosensitive polymer composition; and a curing step for heating the aforementioned positive type photosensitive polymer composition to form a cured film, wherein the aforementioned rinsing step includes a first rinsing step and a second rinsing step, the aforementioned first rinsing step including supplying the aforementioned rinsing solution while the aforementioned support is rotated at a circumferential velocity of equal to or lower than 0.53 m/s, and the aforementioned second rinsing step including supplying the rinsing solution while the aforementioned support is rotated at a circumferential velocity that is higher than the circumferential velocity of the aforementioned first rinsing step.

### TECHNICAL FIELD

The present invention relates to a method for forming a cured film.

### BACKGROUND ART

Conventionally, polybenzoxazole resins and/or polyimide resins, which exhibit higher thermal resistance and excellent electrical and mechanical characteristics, have been employed for surface protective films and interlayer insulating films of semiconductor elements. A positive type photosensitive polymer composition containing a diazoquinone compound serving as a photosensitive material in combination with the above-described resin is employed, in order to provide a simplified process, which employs a polybenzoxazole resin and/or a polyimide resin (see, for example, Patent Document 1). In order to reduce damages caused to the semiconductor elements due to the downsizing of the semiconductor element, the creation of the multiple-layered interconnect by increasing the level of the integration, or the transitions to the chip size package (CSP) or the wafer level package (WLP) in recent years, a positive type photosensitive polymer composition employing a polybenzoxazole resin or a polyimide resin, which exhibits reduced stress, is required. When such positive type photosensitive polymer composition is employed in the real production process, a formation of a micro pattern is needed to be carried out for achieving a downsizing of a semiconductor device.

### RELATED DOCUMENT

### Patent Document

### [Patent Document 1]

Japanese Patent Publication No. H01-46,862 (1989)

### DISCLOSURE OF THE INVENTION

When the formation of the micro pattern is conducted through the conventional developing process and rinsing process, residual substances are remained in the periphery of the patterned opening formed in the developing process, which leads to a problem of reduced size of the patterned opening, which is smaller than desired, in consequence of the formation of the residual substances.

The present inventors have eagerly conducted their investigations, and eventually found the following issues. It is considered that, when a photosensitive polymer composition is dissolved in an alkaline developer solution, the dissolved photosensitive polymer composition is present at higher density in the region of the alkaline developer solution in the side of the photosensitive polymer composition (in the side of a wafer). It was found that the rotation of the wafer at higher speed in a rinsing process causes a removal of the portion of the alkaline developer solution in the upper side (in the side opposite to the wafer) by the centrifugal force before the supply of a rinsing solution. This results in leaving the alkaline developer solution containing the photosensitive polymer composition dissolved therein at higher density on the wafer. It is considered that, once the rinsing solution is supplied, the alkaline concentration in the alkaline developer solution is decreased to cause a precipitation of the photosensitive polymer composition dissolved in the alkaline developer solution, so that the precipitates are adhered and remained around the opening.

The present invention is proposed on the basis of such scientific knowledge. According to one aspect of the present invention, there is provided a method for forming a cured film of a positive type photosensitive polymer composition over a support, including: a coating step for coating the aforementioned support with the aforementioned positive type photosensitive polymer composition; an exposure step for selectively irradiating the aforementioned positive type photosensitive polymer composition with a chemical ray to achieve an exposure; a developing step for developing an exposed section of the aforementioned positive type photosensitive polymer composition with an alkaline developer solution; a rinsing process for rinsing the aforementioned developer solution off with a rinsing solution and removing the exposed section of the aforementioned positive type photosensitive polymer composition; and a curing step for heating the aforementioned positive type photosensitive polymer composition to form a cured film, wherein the aforementioned rinsing step includes a first rinsing step and a second rinsing step, the aforementioned first rinsing step including supplying a rinsing solution while the aforementioned support is rotated at a circumferential velocity of equal to or lower than 0.53 m/s or while the aforementioned support is maintained in the resting state, and the aforementioned second rinsing step including supplying the rinsing solution while the aforementioned support is rotated at a circumferential velocity that is higher than the circumferential velocity of the aforementioned first rinsing step.

According to the invention having such configuration, in the first rinsing step, the support is rotated at a circumferential velocity of equal to or lower than 0.53 m/s, or the rotation of the support is stopped. This allows inhibiting a scattering of the alkaline developer solution presented on the support. Thus, the photosensitive polymer composition in the alkaline developer solution becomes difficult to be precipitated. Besides, even if the photosensitive polymer composition is precipitated, the state of the support having larger amount of the solution remained on the support is maintained since the rotating speed is lower or the rotation of the support is stopped, so that the precipitates are suspended in the solution and thus can be scattered in the second rinsing step. This allows inhibiting the creation of the residual precipitates, thereby providing the cured film having the desired pattern.

According to the present invention, a method for forming a cured film of a positive type photosensitive polymer composition, in which a desired pattern can be formed, is provided.

### BRIEF DESCRIPTION OF THE DRAWINGS

The above and other objects, advantages and features of the present invention will be more apparent from the following description of certain preferred embodiments taken in conjunction with the accompanying drawings.

FIG. 1 is a schematic diagram, representing a process for forming a cured film of a positive type photosensitive polymer composition according to an embodiment of the present invention.

FIG. 2 is a schematic diagram, representing a process for forming a cured film of a positive type photosensitive polymer composition according to another embodiment of the present invention.

### DESCRIPTION OF EMBODIMENTS

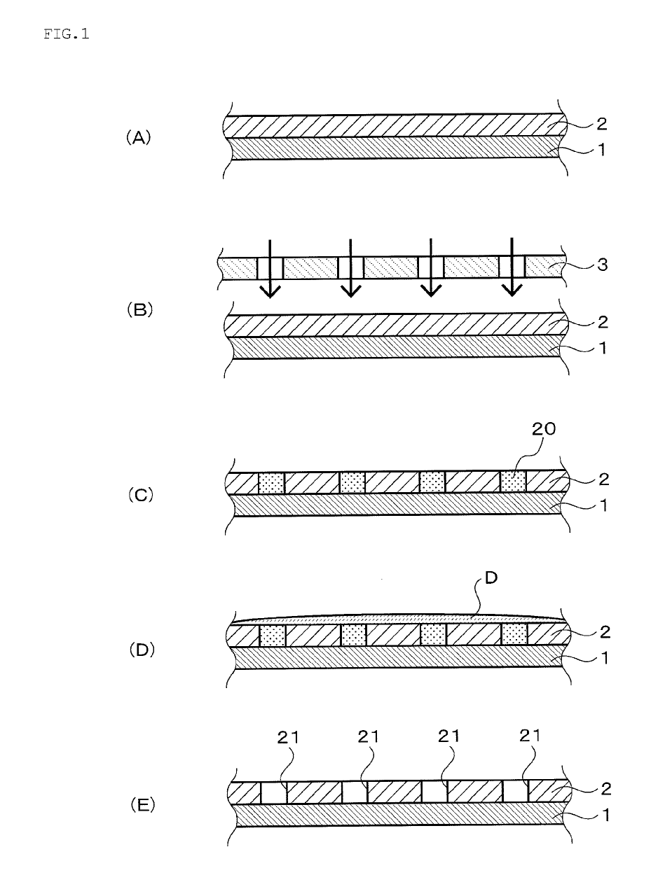

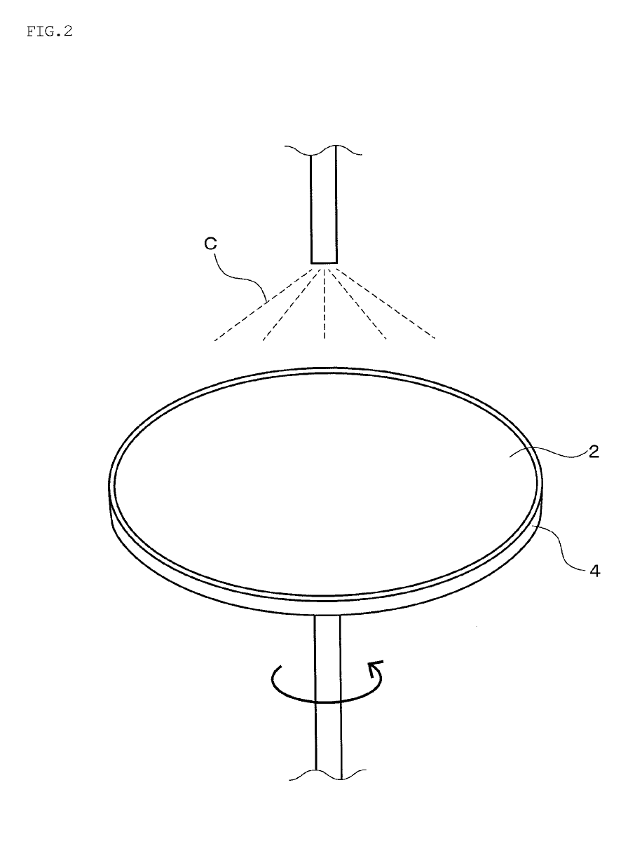

Methods for forming a cured film of a positive type photosensitive polymer composition over a support according to the present invention will be described in detail below, in reference to FIG. 1 and FIG. 2. A method for forming a cured film of a positive type photosensitive polymer composition according to the present embodiment is a method for forming a cured film of a positive type photosensitive polymer composition over a support 1, including: a coating step for coating the aforementioned support 1 with the aforementioned positive type photosensitive polymer composition 2; an exposure step for selectively irradiating the aforementioned positive type photosensitive polymer composition 2 with a chemical ray to achieve an exposure; a developing step for developing exposed sections 20 of the aforementioned positive type photosensitive polymer composition 2 with an alkaline developer solution D; a rinsing process for rinsing the aforementioned alkaline developer solution D off with a rinsing solution and removing the exposed sections 20 of the aforementioned positive type photosensitive polymer composition; and a curing step for heating the aforementioned positive type photosensitive polymer composition to form a cured film, wherein the aforementioned rinsing step includes a first rinsing step and a second rinsing step, in which the aforementioned first rinsing step includes supplying a rinsing solution while the aforementioned support 1 is rotated at a circumferential velocity of equal to or lower than 0.53 m/s or while the aforementioned support is maintained in the resting state (at a circumferential velocity of 0 m/s), and the aforementioned second rinsing step includes supplying the rinsing solution while the aforementioned support 1 is rotated at a circumferential velocity that is higher than the circumferential velocity of the aforementioned first rinsing step.

It will be more specifically described that the method contains: the coating step for coating the support 1 with the positive type photosensitive polymer composition 2 to form a coating film (hereinafter referred to as “coating step”); the exposure step for selectively irradiating the aforementioned positive type photosensitive polymer composition with a chemical ray to achieve an exposure of the aforementioned coating film (hereinafter referred to as “exposure step”); the developing step for repeating one cycle, or two or more cycles of a step including: supplying the alkaline developer solution D on the aforementioned coating film and spreading the aforementioned alkaline developer solution D over the aforementioned coating film and maintaining the aforementioned coating film standing still (hereinafter referred to as “developing step”); the rinsing step for rinsing the aforementioned coating film by supplying the rinsing solution C in the central portion of the aforementioned coating film after the aforementioned developing step and rotating the aforementioned coating film (hereinafter referred to as “rinsing step”); and the curing step for forming the cured film by heating the coating film after the aforementioned rinsing step (hereinafter referred to as “curing step”).

The method for forming the cured film of the positive type photosensitive polymer composition 2 on the support 1 according to the present invention will be described in detail below. The coating step is, as shown in FIG. 1(A), a process step for applying the positive type photosensitive polymer composition 2 over the support 1 (substrate) to produce the coating film. Here, the support 1 is typically, for example, a silicon wafer, a ceramic substrate, an aluminum substrate or the like. The quantity of coating is suitably adjusted so that the final film thickness of the cured product is 0.1 to 30 μm when the coating is carried out on a semiconductor element. The film thickness within the above-described range allows sufficiently exhibiting a function as a protective surface film for the semiconductor element, achieving fine processed pattern with shorter processing time. Typical coating process includes a spin coating process employing a spinner, a spraying coating process employing a spraying coater, a dipping process, a printing process, a roll coating process, and the like.

In the next, as shown in FIGS. 1(B) and (C), the exposure process is conducted. The exposure step is a process step, in which the coating film produced in the coating step is irradiated with a chemical ray so as to create a desired shape of the pattern. The sections irradiated with the aforementioned chemical ray (exposed section 20) are dissolved to be removed in the developing step (discussed later), since the photosensitive diazoquinone compound (B) (the details will be discussed later) in the positive type photosensitive polymer composition 2, which constitutes the coating film, is chemically reacted to generate an acid. The chemical ray available here may include ultraviolet ray, visible ray and the like, and the ray having a wave length of 200 to 500 nm is preferable. More specifically, in order to obtain the desired shape of the pattern, an article referred to a photo mask, a reticle or the like (defined as photo mask or the like 3) is prepared by coating a surface of a quartz glass substrate or the like with, for example, chromium to provide shields, and the aforementioned coating film is irradiated with a chemical ray through such photo mask 3. A contact exposure, a proximity exposure, a unit-magnification projection exposure, a reduced-magnification projection exposure, a scan exposure, and the like may be suitably selected for the exposure method of the exposure equipment, according to the positional relation between the aforementioned photo mask or the like 3 and the support 1 coated with the positive type photosensitive polymer composition 2 or according to the reduction ratio between the pattern provided on the aforementioned photo mask or the like 3 and the desired pattern.

The developing step is conducted for the purpose of obtaining a relief pattern composed of the positive type photosensitive polymer composition 2 by dissolving and removing the sections (exposed sections 20) of the aforementioned coating film irradiated with the chemical ray in the aforementioned exposure step with the alkaline developer solution D as shown in FIG. 1(D). Typical developing method includes a puddling process and the like, but it is not limited thereto. The developing process through the aforementioned puddling process includes a process step, in which the alkaline developer solution D is supplied over the exposed coating film so as to uniformly spread over the film and then the supply of the alkaline developer solution is stopped to provide and maintain a state, in which the alkaline developer solution is disposed on the coating film (the state, in which the coating film is covered with the film of the alkaline developer solution D), so that the exposed sections 20 of the coating film are dissolved to be removed, and such step is referred to as a standing-still step. Since the unexposed sections are also in contact with the alkaline developer solution D in this time, portions of the coating film surface layer are also dissolved (also referred to as film reduction). For example, when a positive type photosensitive polymer composition containing an alkaline-soluble resin and a photosensitive diazoquinone compound is employed, the mechanism of such developing process can be described as follows. Since the photosensitive diazoquinone compound in the positive type photosensitive polymer composition 2 of the exposed sections is chemically reacted to generate an acid, the solubility of the exposed sections for the alkaline developer solution D is enhanced. On the contrary, in the unexposed portions, azo-coupling reaction is occurred between the alkaline-soluble resin and the photosensitive diazoquinone compound in the presence of the alkaline developer solution D to form a layer, which exhibits poor solubility to the alkaline developer solution, on the surface layer of the coating film, and therefore the solubility to the alkaline developer solution D is reduced. Since the solubility to the alkaline developer solution D is different between the exposed sections and the unexposed portions as described above, a relief pattern composed of the positive type photosensitive polymer composition 2 can be produced by conducting the developing process.

Preferable examples of the aforementioned alkaline developer solution includes aqueous solutions containing aqueous solutions of alkaline compounds such as: inorganic alkali compounds such as sodium hydroxide, potassium hydroxide, sodium carbonate, sodium silicate, sodium metasilicate, aqueous ammonia and the like; primary amines such as ethylamine, n-propyl amine and the like; secondary amines such as diethylamine, di-n-propyl amine and the like; tertiary amines such as triethylamine, methyl diethylamine and the like; alcoholamines such as dimethylethanolamine, triethanolamine and the like; and quaternary ammonium salts such as tetramethylammonium hydroxide, tetraethylammonium hydroxide and the like, with a suitable amount of an additional water-soluble organic solvent such as alcohols including methanol, ethanol and the like, and/or a surfactant. Here, the viscosity of the alkaline developer solution at 25 degrees C. is equal to or higher than 0.8 mPa·s and equal to or lower than 3.0 mPa·s.

While the step of developing with the aforementioned alkaline developer solution may consist of a single cycle of the supply of the developer solution (a single cycle of the standing-still process), the step may alternatively consist of multiple cycles, in order to reduce the developing time. Here, the developing time is the total time, in which the alkaline developer solution is rested on the coating film. When the step is constituted of a single cycle of the aforementioned standing-still operation, the alkaline-soluble resin in the positive type photosensitive polymer composition 2 constituting the coating film causes an action with the alkaline compound in the alkaline developer solution D to provide gradually reduced alkaline concentration of the alkaline developer solution D, such that the developing rate is reduced. On the contrary, when multiple cycles of the aforementioned standing-still operation are conducted, higher level of the alkaline concentration in the alkaline developer solution D can be maintained to allow reducing the developing time. When multiple cycles of the aforementioned standing-still operation are conducted, the support 1 may be, for example, rotated after the first cycle of the standing-still operation is finished to remove the alkaline developer solution D from the support 1. Then, another alkaline developer solution D may also be supplied on the coating film again to form a new film of the alkaline developer solution D on the coating film.

On the contrary, while the consecutive multiple cycles of the standing-still operation with the aforementioned alkaline developer solution D are conducted to reduce the developing time, this may cause excessively increased alkaline concentration in the alkaline developer solution D, which may cause variations in the shapes and the sizes of the openings 21 in the coating film. In addition, the execution of the consecutive multiple cycles of the standing-still operation with the aforementioned alkaline developer solution D causes increased consumption of the alkaline developer solution D, causing a problem of an increase in the production cost. Preferable number of consecutive cycles of the standing-still operation with the aforementioned alkaline developer solution D is one to five, and one cycle to four cycles are particularly preferable. The above-described range of the consecutive cycles allows providing reduced variations in the shapes and the sizes of the openings 21 in the coating film, and further allows providing reduced production cost.

The rinsing step is conducted for the purpose of removing the developer solution, which has been adhered to the coating film after the developing step. The rinsing step is the process step for supplying a rinsing solution C (for example, water) over the coating film after the developing step (for example, the center section of the coating film), and rotating the coating film to rinse the coating film, as shown in FIG. 2. The location of supplying the rinsing solution C is not limited to the center section of the coating film, and arbitrary multiple locations may be provided between the center section and the circumference of the coating film. The type of the aforementioned rinsing solution C is not particularly limited, and for example, distilled water may be employed. Since it is necessary to scatter the developer solution, the mixture of the developer solution and the rinsing solution or the rinsing solution from the coating film by the rotation in conventional rinsing step, when the supply of the rinsing solution is started, it is common to supply the rinsing solution while the coating film is rotated at a circumferential velocity of equal to or higher than 1 m/s, and there was a case that a residual substance is observed in the opening 21. For example, Japanese Patent No. 4,678,772 describes that the rinse was conducted while rotating the substrate at equal to or higher than 1,000 rpm. Although there is no description on the diameter of the substrate, it is generally considered that a silicon wafer serving as the substrate has a diameter of 4 inches at a minimum and 12 inches at a maximum, and therefore it is predicted that the circumferential velocity is equal to or higher than 5.2 m/s for 4 inch-wafer, and equal to or higher than 15.7 m/s for 12 inch-wafer. Here, the circumferential velocity is a velocity of a rotating object (coating film in this case) at a position of the maximum radius, and the circumferential velocity is represented by 2πnR where number of rotations is n and the maximum radius is R.

The mechanism of generating the residual substance observed in the aforementioned opening 21 is considered as follows. When the positive type photosensitive polymer composition containing the alkaline-soluble resin and the photosensitive diazoquinone compound is, for example, employed, the exposed portions of the coating film cause the azocoupling reaction between the alkaline-soluble resin and the photosensitive diazoquinone compound in the presence of the alkaline developer solution D as described above, and therefore a layer exhibiting poor solubility to the alkaline developer solution D is formed on the surface layer of the coating film, and on the other hand, the unexposed portions of the coating film are to be dissolved with the alkaline developer solution, although the dissolution gradually proceeds. When the coating film is dissolved in the alkaline developer solution D, the dissolved compounds are not uniformly distributed in the alkaline developer solution D but the most of the dissolved compounds are remained on the coating film interface and the periphery thereof. When the rinsing step is conducted in such state, the rotation of the coating film at the circumferential velocity of equal to or higher than 1 m/s allows the most of the alkaline developer solution D are more rapidly eliminated from the coating film. It is, however, considered that the alkaline developer solution D disposed in the coating film interface and the periphery thereof is difficult to be eliminated, and thus is remained on the coating film. It is further considered as described above that the alkaline developer solution D contains most of the dissolved compounds of the coating film, and the supply of the rinsing solution C on the coating film in such state causes the considerable decrease of the alkaline concentration in the alkaline developer solution D, so that the positive type photosensitive polymer composition, which has been dissolved in the alkaline developer solution D, precipitates, and thus the residual substances are observed particularly in the opening 21, which contains larger quantity of the dissolved compounds. It is also considered that, when the rinsing solution is supplied simultaneously with rotating the coating film, the portion of the alkaline developer solution D, which rests in the substantially circumference section of the coating film, is eliminated before the rinsing solution is supplied by the action of the centrifugal force, and therefore it is considered that the positive type photosensitive polymer composition precipitates in such state as described above, and the residual substance is observed particularly in the opening 21, where larger amount of the dissolved components are present. Here, it is estimated that the residual substances are from the dissolved unexposed portion of the coating film.

The present inventors found from the results of the earnest investigations on the basis of the above-described mechanism of generating the residual substances that the generation of the residual substances can be reduced by employing the rinsing step, which includes: the first rinsing step, in which the aforementioned rinsing solution C is supplied, while the support 1 having the positive type photosensitive polymer composition 2, which is coated thereon, exposed and developed, is rotated at the circumferential velocity of equal to or lower than 0.53 m/s or while the rotation is stopped; and the second rinsing step, in which the aforementioned rinsing solution C is supplied while the support is rotated at the circumferential velocity higher than that employed in the aforementioned first rinsing step. The configuration of the first rinsing step conducted in the state of rotating the support at the circumferential velocity of equal to or lower than 0.53 m/s or in the state of stopping the rotation of the support prevents the alkaline developer solution rested on the coating film from being rapidly removed from the coating film. The alkaline concentration in the alkaline developer solution D on the support can be gradually reduced by employing the configuration, in which the rinsing solution is supplied while rotating the support at such lower circumferential velocity or in the state that the rotation is stopped, thereby inhibiting the precipitation of the positive type photosensitive polymer composition to carry out the rinsing treatment. Even if the rinsing solution is supplied at higher supply rate so that the alkaline concentration in the alkaline developer solution D is rapidly reduced to cause the precipitation of the photosensitive polymer composition, the state, in which larger amount of the solution is remained on the support 1, is maintained, since the rotating speed is lower or the rotation is stopped, and thus the precipitates are suspended in the solution and thus can be scattered in the second rinsing step. This allows inhibiting the creation of the residual precipitates (residual substances), thereby presenting the cured film having the desired pattern. On the contrary, if the circumferential velocity is higher than 0.53 m/s, the portion of the alkaline developer solution D in the side of the upper portion (in the side opposite to the support 1) is removed by the centrifugal force before the rinsing solution C is supplied. Even if the rinsing solution C is supplied in such state, the precipitates are easily adhered to the opening 21 of the coating film, and thus the precipitates are remained in the opening 21. The rotating speed (circumferential velocity) of the support 1 in the first rinsing step is equal to or lower than 0.53 m/s, and the precipitation of the residual substance in the opening 21 can be inhibited by selecting the circumferential velocity as equal to or lower than 0.53 m/s. While no residual substance is also observed in the opening for 0 m/s, it is preferable to rotate the support 1 in order to create the opening 21 with higher accuracy, and the circumference velocity of equal to or higher than 0.21 m/s is more preferable. No problem would be caused whether the circumferential velocity is constant or variable, as long as the circumferential velocity is within the above-described range. In addition, the preferable duration time for the above-described first rinsing step may be equal to or longer than 1 second and equal to or shorter than 15 seconds, and particularly preferable time may be equal to or longer than 5 seconds and equal to or shorter than 10 seconds. The time required for gradually reducing the alkaline concentration of the alkaline developer solution D on support can be ensured by selecting the time as equal to or longer than 1 second. On the other hand, the process time of equal to or shorter than 15 second can prevent the state of causing a concentration distribution of the alkaline developer solution over the support from being maintained for longer time, and thus the dimensional accuracy of the opening 21 in the surface of the coating film can be maintained.

The flow rate of the rinsing solution C for supplying over the coating film may be preferably 0.5 to 1.5 L/min., and more preferably 0.7 to 1.3 L/min. The flow rate within the above-described range allows rapidly removing the developer solution, which has been adhered to the coating film, and also allows preventing the considerable decrease in the concentration of the alkaline developer solution D, so that the generation of the residual substance can be inhibited. In addition, no problem would be caused whether the flow rate of the rinsing solution C in the rinsing step is constant or variable. While larger amount of the rinsing solution C and the alkaline developer solution D are present on the support 1 in the first rinsing step, only smaller amount of the rinsing solution C and the alkaline developer solution D are removed from the support 1 during the supply of the rinsing solution C.

After the first rinsing step, the second rinsing step is conducted. The second rinsing step may employ a rotating speed (circumferential velocity), which is higher than the circumferential velocity employed in the first rinsing step, and in particular, it is preferable to rotate at the circumferential velocity of 3 to 40 m/s in the second rinsing step. The circumferential velocity of equal to or higher than 3 m/s allows ensuring the removal of the alkaline developer solution D, which has been rested on the coating film and the support 1, from the coating film and the support 1. On the other hand, it is considered that the circumferential velocity of equal to or lower than 40 m/s provides an advantageous effect of reducing creation of the turbulent flow around the rotating support. In the second rinsing step, the developer solution, in which the alkaline concentration has been gradually reduced in the first rinsing step, is eliminated. No problem would be caused whether the circumferential velocity of the support 1 in the second rinsing step is constant or variable. In addition, the flow rate of the rinsing solution on this occasion is similar to that employed in first rinsing step. In the case that the support 1 is rotated in the first rinsing step, the rotation of support 1 may not stopped and the rotating velocity of the support 1 may be increased in the transition from the first rinsing step to the second rinsing step. It is preferable to conduct the second rinsing step for, for example, equal to or longer than 5 seconds and equal to or shorter than for 30 seconds by supplying the rinsing solution after reaching to a predetermined circumferential velocity. This results in removing the developer solution. Here, the rotation of the support 1 conducted during the transition to the second rinsing step after the end of the first rinsing step should cause gradual removal of the rinsing solution C and the alkaline developer solution D from the support 1. Nevertheless, since the first rinsing step has been already conducted, the alkaline developer solution D containing the dissolved coating film at high concentration would not be remained in the interface of the coating film, unlikely in the conventional process.

In the curing step according to the present invention, the coating film processed through the aforementioned rinsing step is heated to obtain a final pattern. The preferable heating temperature may be, for example, 160 degrees C. to 380 degrees C., and more preferably 180 degrees C. to 350 degrees C. An inert gas such as nitrogen gas and the like may be introduced through the heating apparatus in the heating process to reduce unwanted oxidation of the coating film.

During or after the process for coating the aforementioned positive type photosensitive polymer composition 2 over the support 1, the positive type photosensitive polymer composition 2 adhered on the back surface, on the side surfaces or in vicinity of the circumference, of the support 1, may be dissolved with a solvent to reduce the pollution to the device. Typical examples of the aforementioned solvent include N-methyl-2-pyrrolidone, γ-butyrolactone, N,N-dimethylacetamide, dimethylsulfoxide, diethyleneglycol dimethyl ether, diethyleneglycol diethyl ether, diethyleneglycol dibutyl ether, propyleneglycol monomethyl ether, dipropyleneglycol monomethyl ether, propyleneglycol monomethyl ether acetate, methyl lactate, ethyl lactate, butyl lactate, methyl-1,3-butyleneglycol acetate, 1,3-butyleneglycol-3-monomethyl ether, methyl pyruvate, ethyl pyruvate, methyl-3-methoxy propionate and the like, though it is not limited thereto. A single solvent may be employed alone, or a mixture may be employed.

In addition, a pre-baking of the aforementioned coating film may be conducted after the aforementioned coating step to vaporize the solvent, thereby drying the coating film. Typical method of the aforementioned pre-baking process may employ a heating apparatus such as a hot plate, an oven and the like, and a temperature of 60 to 140 degrees C. may be preferable, and more preferably 100 to 130 degrees C. An inert gas such as nitrogen gas and the like may be introduced through the heating apparatus in the heating process to reduce unwanted oxidation of the coating film.

Now, the positive type photosensitive polymer composition 2 will be described in detail. Here, it is intended that the following description is for illustrations and the positive type photosensitive polymer composition 2 is not limited to the following descriptions. An exemplary implementation for the positive type photosensitive polymer composition 2 according to the present invention may contain an alkaline-soluble resin (A) and a photosensitive diazoquinone compound (B).

Typical examples of the aforementioned alkaline-soluble resin (A) include, for example: cresol novolac resins; hydroxystyrene resins; acrylic based resins such as methacrylic acid resins, methacrylate resins and the like; cyclic olefin based resins having hydroxyl group, carboxylic group and the like; polyamide based resins; and the like. Among these, polyamide based resins are preferable due to their better thermal resistance and better mechanical characteristics, and more specifically polyamide based resin may be at least any one of: a resin having at least one of polybenzoxazole structure and polyimide structure and having hydroxyl group, carboxylic group, ether group or ester group in a main chain or a side chain; a resin having polybenzoxazole precursor structure; a resin having polyimide precursor structure; and a resin having polyamic acid ester structure. Such type of the polyamide based resin may include, for example, a polyamide based resin having a structure represented by the following formula (1). In addition, repeating unit in the structure represented by the following formula (1) may preferably 2 to 1,000.

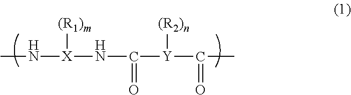

In formula (1), X and Y are organic groups; R₁ is hydroxyl group, —O—R₃, alkyl group, acyl oxy group, or cycloalkyl group, and may be same or different; R₂ is any one of hydroxyl group, carboxylic group, —O—R₃ and —COO—R₃, and may be same or different; m and n are an integer of 0 to 8; R₃ is an organic group of C1 to C15; when a plurality of R₁ is contained, these may be different or same; when no hydroxyl group is contained as R₁, at least one of R₂ must be carboxylic group; when no carboxylic group is contained as R₂, at least one of R₁ must be hydroxyl group.

In the polyamide based resin containing the structure represented by the aforementioned general formula (1), —O—R₃ as the substitutional group of X and —O—R₃ and —COO—R₃ as the substitutional group of Y are groups protected by R₃, which is an organic group of C1 to C15, for the purpose of adjusting the solubility of hydroxyl group and carboxylic group in the alkaline water solution, and may protect hydroxyl group and carboxylic group as required. Examples of R₃ include formyl group, methyl group, ethyl group, propyl group, isopropyl group, tertiary butyl group, tertiary butoxycarbonyl group, phenyl group, benzyl group, tetrahydrofuranyl group, tetrahydropyranyl group and the like.

Dewatering cyclization is caused by heating the polyamide based resin as described above to obtain a thermally resistant resin in a form of a polyimide resin or a polybenzoxazole resin, or a copolymer of the both.

The polyamide based resin having the structure represented by the aforementioned general formula (1) is obtained by a reaction between, for example, a compound selected from diamine, or bis(aminophenol), 2,4-diamino phenol and the like, containing X, and a compound selected from dicarboxylic acid or dicarboxylic acid dichloride, dicarboxylic acid derivative and the like, containing Y. Here, in the case of dicarboxylic acid, activated ester type dicarboxylic acid derivative, which is previously reacted with 1-hydroxy-1,2,3-benzotriazole and the like in order to enhance reaction yield, may be employed.

X in the aforementioned general formula (1) includes, for example: aromatic compound group such as benzene ring, naphthalene ring and the like; heterocyclic compound group such as bisphenol group, pyrrole group, furan group and the like; and siloxane compound group, and more specifically, preferably includes functional groups represented by the following formula (2). One of these may be employed alone, or combination of two or more of these may be employed, as required.

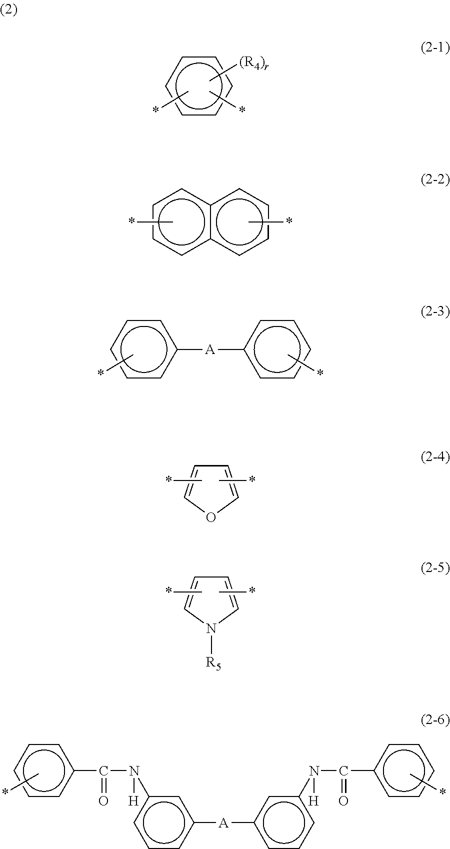

In formula (2), * indicates to be bound to NH group; A represents —CH₂—, —CH(CH₃)—, —C(CH₃)₂—, —O—, —S—, —SO₂—, —CO—, —NHCO—, —C(CF₃)₂—, or single bond; R₄ represents any one selected from alkyl group, alkyl ester group and halogen atom, and may be same or different; R is an integer number, R=0 to 2.

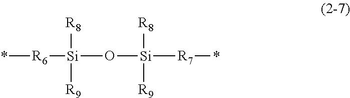

In formula (2-7), * indicates to be bound to NH group; R₆to R₉ are organic groups.

As shown in the general formula (1), 0 to 8 of R₁ are coupled to X (In formula (2), R₁ is not shown).

Particularly preferable examples of the formula (2) include the examples represented by the following formula (3), which exhibits particularly enhanced thermal resistance and mechanical characteristics.

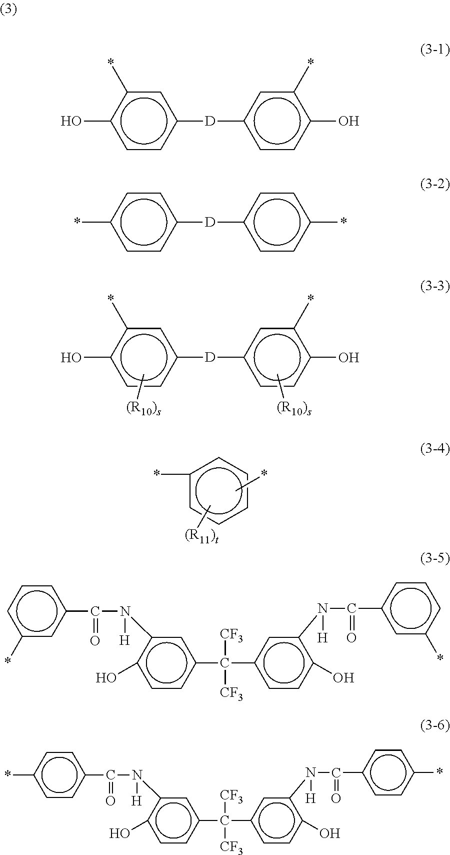

In formula (3), * indicates to be bound to NH group; D represents —CH₂—, —CH (CH₃)—, —C(CH₃)₂—, —O—, —S—, —SO₂—, —CO—, —NHCO—, —C(CF₃)₂—, or single bond; R₁₀ is any of alkyl group, alkoxy group, acyl oxy group and cycloalkyl group, and may be same or different; R₁₁ represents any one selected from alkyl group, alkyl ester group and halogen atom, and may be same or different; s and t are integer numbers, s=1 to 3 and t=0 to 2.

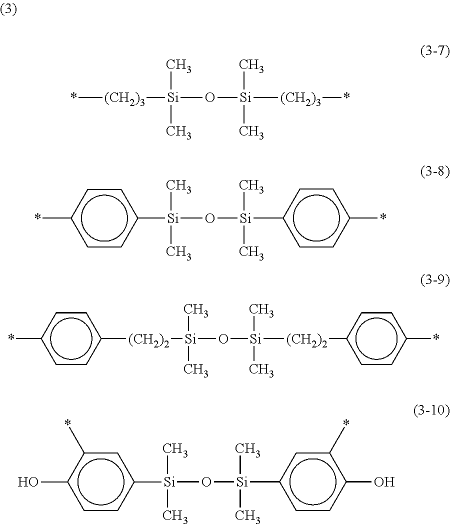

In formula (3), * indicates to be bound to NH group.

In addition, Y in the aforementioned general formula (1) is an organic group, and includes the same groups as indicated for the aforementioned X, and includes, for example: aromatic compound group such as benzene ring, naphthalene ring and the like; and heterocyclic compound group such as bisphenol group, pyrrole group, pyridine group, furan group and the like, and more specifically, preferably includes functional groups represented by the following formula (4). One of these may be employed alone, or combination of two or more of these may be employed.

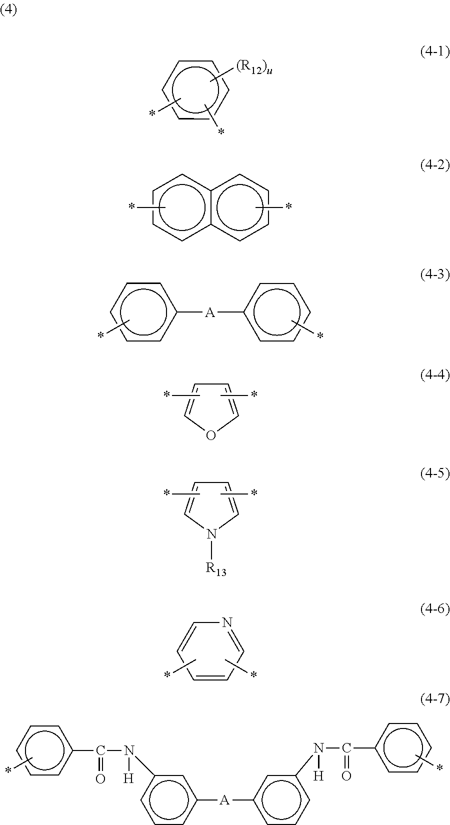

In formula (4), * indicates to be bound to C═O group; A represents —CH₂—, —C(CH₃)₂—, —O—, —S—, —SO₂—, —CO—, —NHCO—, —C(CF₃)₂—, or single bond; R₁₂ represents any one selected from alkyl group, alkyl ester group and halogen atom, and may be same or different; R₁₃ represents any one selected from atomic hydrogen, alkyl group, alkyl ester group and halogen atom; u is an integer number, u=0 to 2.

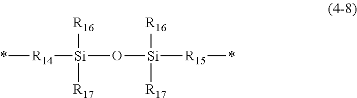

In formula (4-8), * indicates to be bound to C═O group; R₁₄ to R₁₇ are organic groups.

As shown in the general formula (1), 0 to 8 of R₂ are coupled to Y (In formula (4), R₂ is not shown).

Particularly preferable examples of the formula (2) include the examples represented by the following formula (5) and formula (6), which exhibits particularly enhanced thermal resistance and mechanical characteristics. While specific structures derived from tetracarboxylic acid dianhydride are exemplified in the following formula (5), which are configured that the sites coupled to C═O group are both meta sites and both para sites, an alternative structure coupled in meta sites and para sites may be employed.

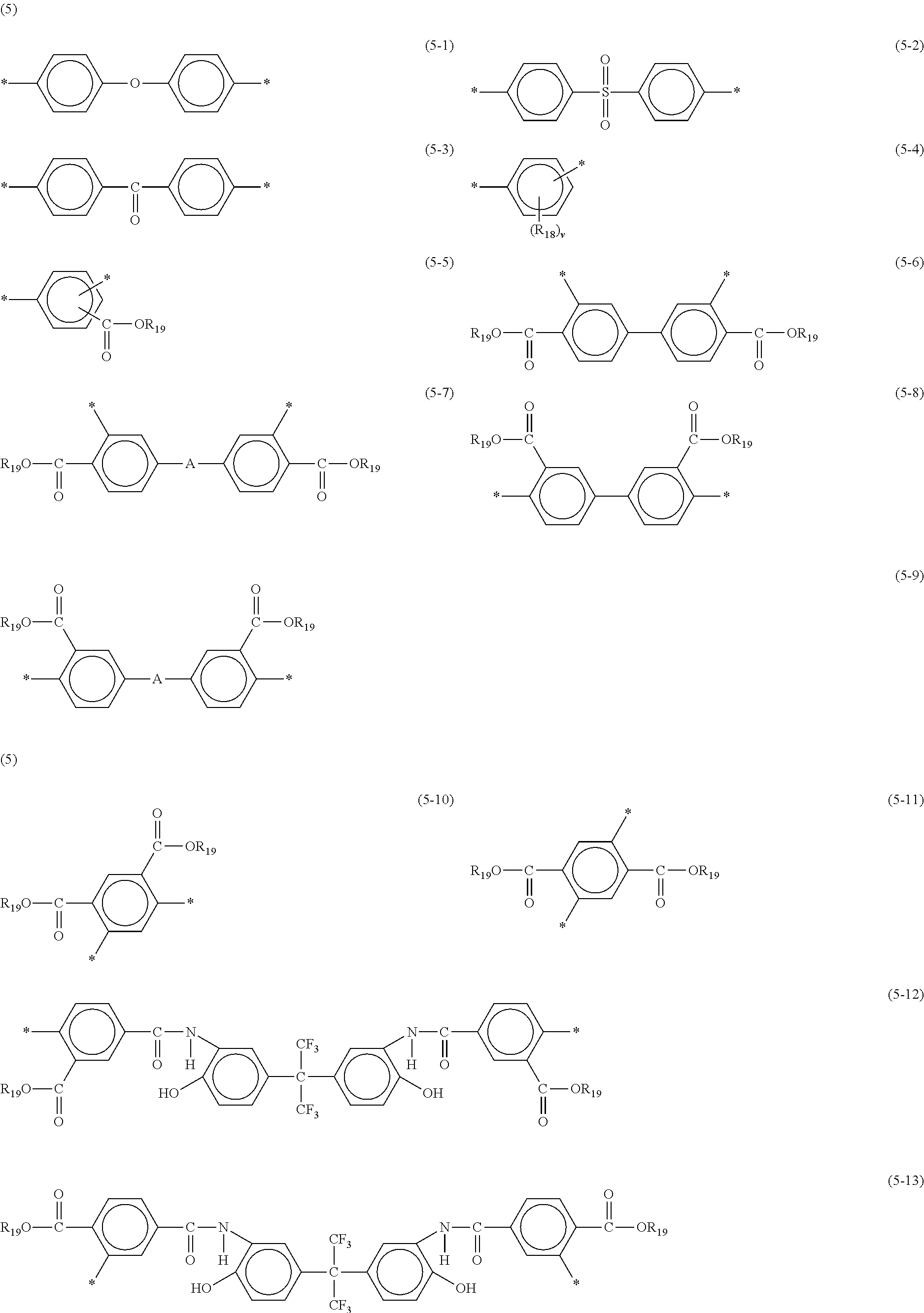

In formula (5), * indicates to be bound to C═O group; R₁₈ represents any one selected from alkyl group, alkyl ester group, alkylether group, benzyl ether group, and halogen atom, and may be same or different; R₁₉ represents atomic hydrogen or an organic group of C1 to C15, a part of which may be substituted; v is an integer of 0 to 2; A is —C(CH₃)₃—, —O—, —SO₂—, —CO— or —C(CF₃)₂—.

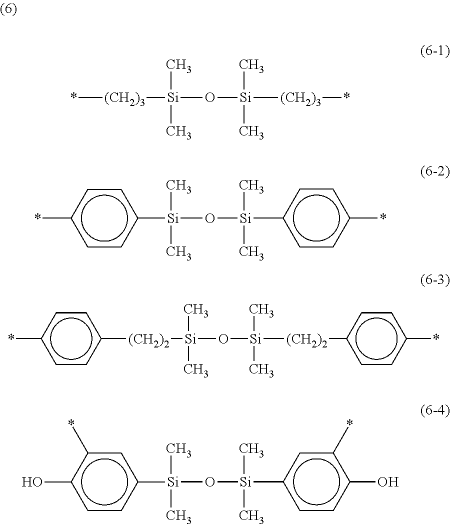

In formula (6), * indicates to be bound to C═O group.

In addition, in the polyamide based resin represented by the above-described general formula (1), terminal amino group in the polyamide based resin may be preferably capped with aliphatic group having at least one alkenyl group or alkynyl group, or with an acid anhydride or an acid derivative containing cyclic compound group to create amide. This allows providing improved storage stability of the positive type photosensitive polymer composition. Such acid anhydrides having aliphatic group or cyclic compound group at least one of alkenyl group and alkynyl group, which are reactive with amino group in the polyamide based resin, includes maleic anhydrides, bicyclo [2.2.1] hepta-5-ene-2,3-dicarboxylicacid anhydride, 4-ethynylphthalic anhydride, 4-(phenyl-ethynyl)phthalic anhydride, and the like. For example, typical acid anhydrides include compounds represented by the following formula (7), and the like. Acid derivatives having aliphatic group or cyclic compound group at least one of alkenyl group and alkynyl group, which are reactive with amino group in the polyamide based resin, are acid derivatives derived by substituting OH group of carboxylic group in carboxylic acid or polyvalent carboxylic acid having aliphatic group or cyclic compound group at least one of alkenyl group and alkynyl group, and typically include halides of carboxylic acid, and for example, the compounds represented by the following formula (8) is preferable. One of these may be employed alone, or combination of two or more of these may be employed.

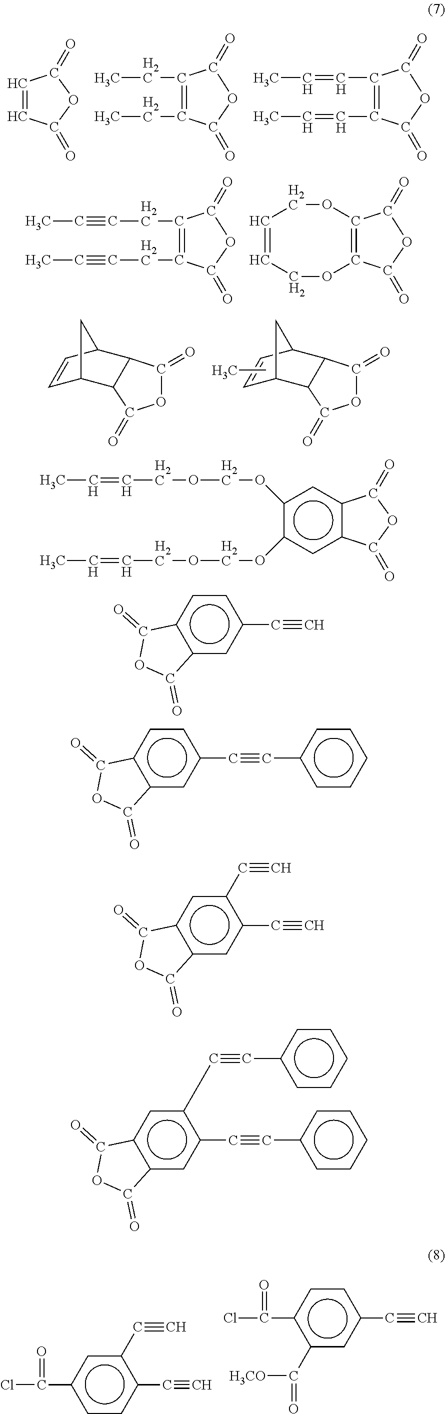

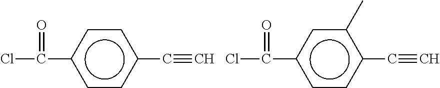

Among these, groups selected from the following formula (9) are particularly preferable. This allows providing improved storage stability.

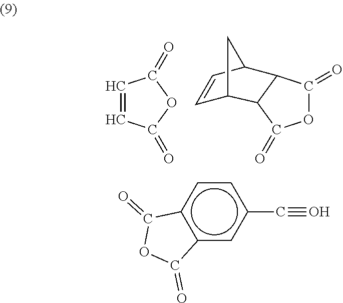

In addition, it is not necessary to be limited to the aforementioned method, and terminal acid contained in the aforementioned polyamide based resin may be reacted with an amine derivative containing aliphatic group or cyclic compound group having at least one alkenyl group or alkynyl group to provide a cap as amide.

Typical example of photosensitive diazoquinone compound (B) is, for example, ester of a phenolic compound with 1,2-naphthoquinone-2-diazide-5-sulfonic acid or 1,2-naphthoquinone-2-diazide-4-sulfonic acid. More specifically, it may exemplify ester compounds represented by formula (10) to formula (13). One of these may be employed alone, or combination of two or more of these may be employed.

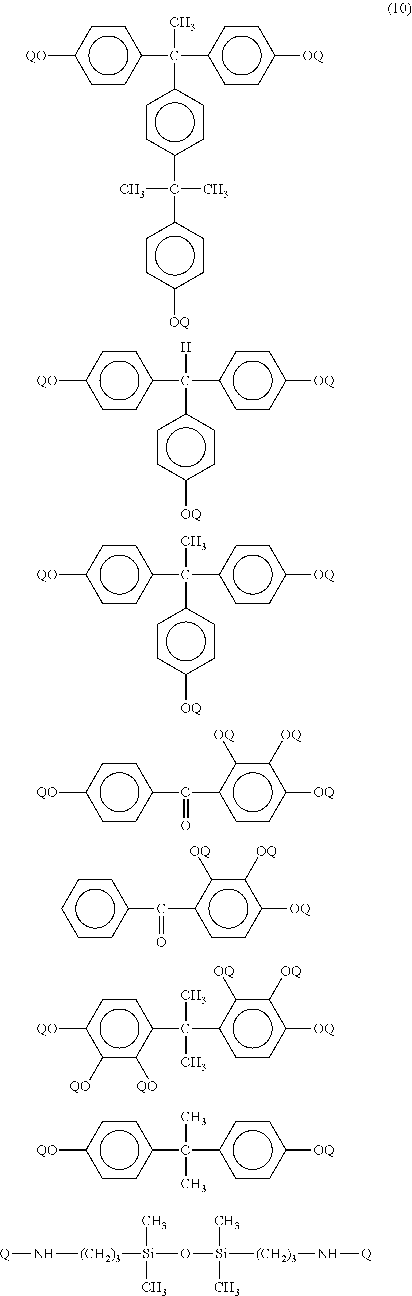

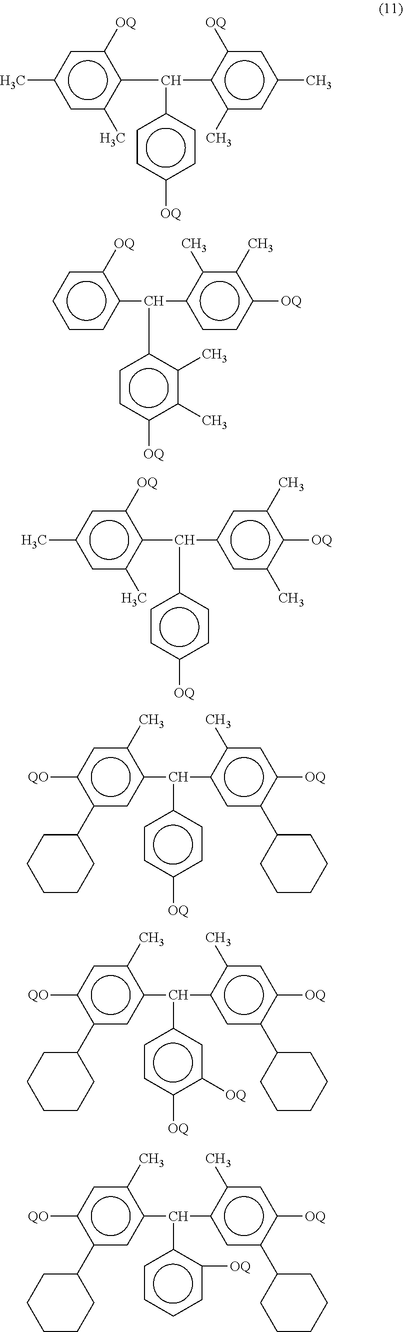

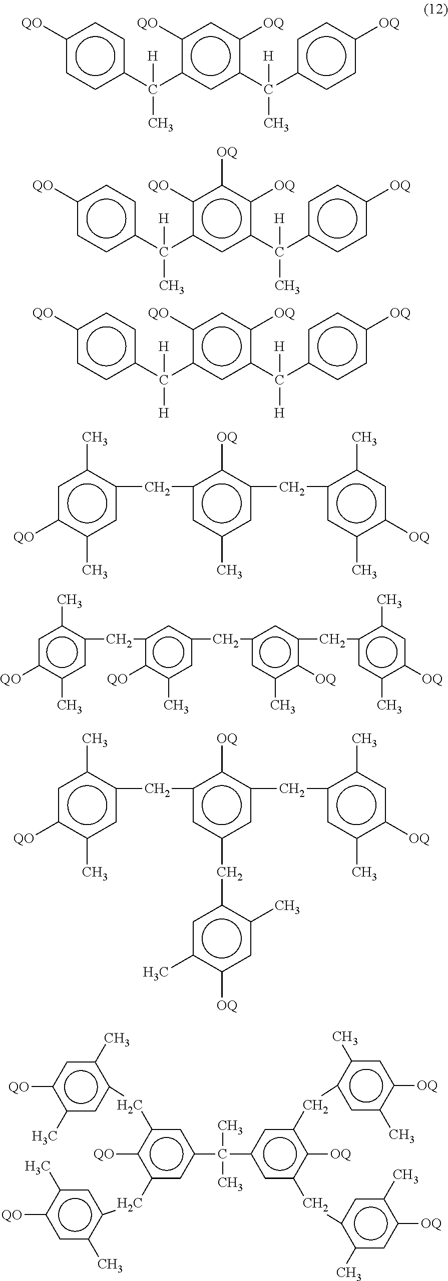

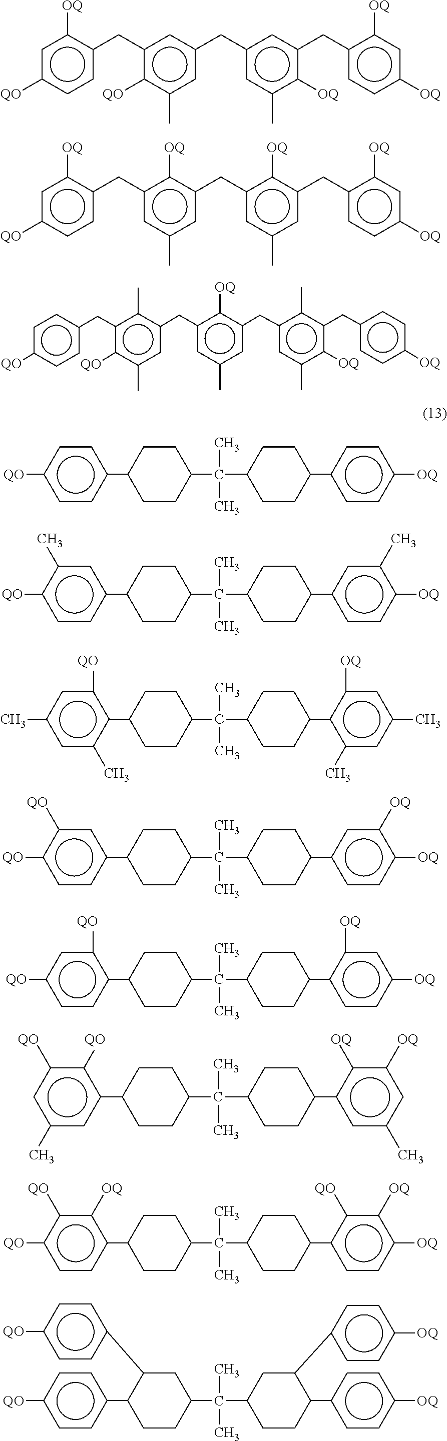

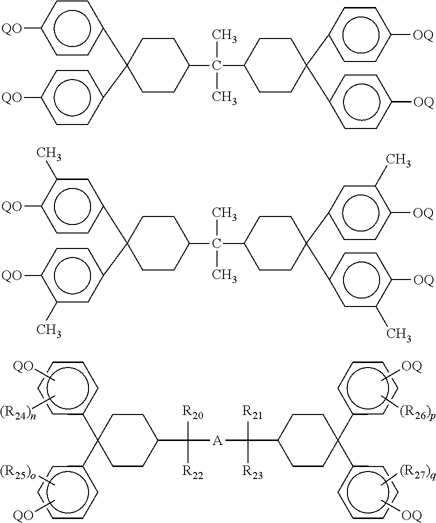

In formula, A represents an organic group; each of R₂₀ to R₂₃ is atomic hydrogen or alkyl group, and each of R₂₄ to R₂₇ is one selected from atomic hydrogen, hydroxyl group, halogen atom, alkyl group, alkoxy group, alkenyl group and cycloalkyl group, and may be same or different; n, o, p and q are integer of 0 to 4.

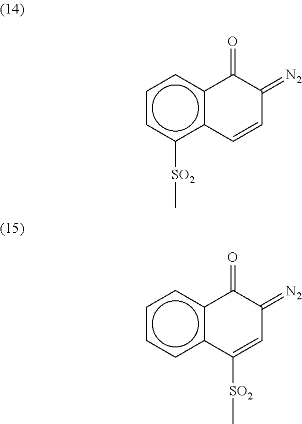

In formula (13), Q is selected from any one of atomic hydrogen, formula (14) and formula (15). Here, among Qs of the respective compounds, at least one is formula (14) or formula (15).

The adding quantity of the photosensitive diazoquinone compound (B),may be preferably 1 to 50 parts by weight (pbw) over 100 pbw of the alkaline-soluble resin (A). More preferably, the adding quantity is 10 to 40 pbw. The adding quantity within the above-described range provides particularly enhanced sensitivity.

The positive type photosensitive polymer composition may contain acrylic-based, silicone-based, fluorine-based, or vinyl-based leveling agent, or additives such as silane coupling agent and the like as required. The aforementioned silane coupling agent typically includes: 3-glycidoxypropyl trimethoxy silane, 3-glycidoxypropylmethyl diethoxy silane, 3-glycidoxypropyl triethoxy silane, p-styryl trimethoxy silane, 3-methacryloxypropylmethyl dimethoxy silane, 3-methacryloxypropyl trimethoxy silane, 3-methacryloxypropylmethyl diethoxy silane, 3-methacryloxypropyl triethoxy silane, 3-acryloxypropyl trimethoxy silane, N-2-(aminoethyl)-3-aminopropylmethyl dimethoxy silane, N-2-(aminoethyl)-3-aminopropyl trimethoxy silane, N-2-(aminoethyl)-3-aminopropyl triethoxysilane, 3-aminopropyl trimethoxy silane, 3-aminopropyl triethoxy silane, N-phenyl-3-aminopropyl trimethoxy silane, 3-mercaptopropylmethyl dimethoxy silane, 3-mercaptopropyl trimethoxy silane, bis(triethoxypropyl)tetrasulphido, 3-isocyanatepropyl triethoxy silane and the like, though it is not limited thereto.

It is preferable in the present invention to dissolve these components in a solvent to prepare a varnish form for the use. Typical solvents include N-methyl-2-pyrrolidone, γ-butyrolactone, N,N-dimethylacetamide, dimethylsulfoxide, diethyleneglycol dimethyl ether, diethyleneglycol diethyl ether, diethyleneglycol dibutyl ether, propyleneglycol monomethyl ether, dipropyleneglycol monomethyl ether, propyleneglycol monomethyl ether acetate, methyl lactate, ethyl lactate, butyl lactate, methyl-1,3-butyleneglycolacetate, 1,3-butyleneglycol-3-monomethyl ether, methyl pyruvate, ethyl pyruvate, methyl-3-methoxy propionate, and the like, and a single solvent may be employed alone, or a mixture may be employed. The present application claims priority based on Japanese Patent Application No. 2010-156,274 filed on Jul. 9, 2010, the whole contents of which are herein incorporated by reference.

### EXAMPLES

Hereinafter, the present invention will be specifically described by showing Examples.

### Example 1

### Synthesis of Alkaline-Soluble Resin (A-1)

443.21 g (0.9 mol) of dicarboxylic acid derivative (activated ester), which was obtained by a reaction of 0.9 mol of diphenylether-4,4′-dicarboxylic acid and 1.8 mol of 1-hydroxy-1,2,3-benzotriazole, and 366.26 g (1 mol) of hexafluoro-2,2-bis(3-amino-4-hydroxyphenyi) propane were introduced into a four-necked separable flask equipped with a thermometer, a stirrer a raw materials-supply port, and a dried nitrogen gas supply tube, and 3,200 g of N-methyl-2-pyrrolidone was added thereto to be dissolved. Thereafter, a reaction was carried out by employing an oil bath at 75 degrees C. for 12 hours. In the next, 34.43 g (0.2 mol) of 4-ethynylphthalicanhydride, which had been dissolved in 100 g of N-methyl-2-pyrrolidone, was added, and further was stirred for additional 12 hours to complete the reaction. The reaction mixture was filtered out, and then, the reaction mixture was supplied into a solution of water/isopropanol=3/1 (volumetric ratio), and the created precipitates were filtered out, and was sufficiently rinsed with water, and then was dried to obtain the target alkaline-soluble resin (A-1).

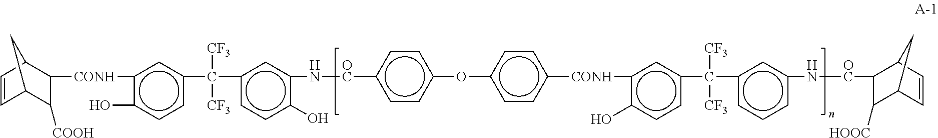

### Manufacture of Positive Type Photosensitive Polymer Composition

100 g of synthesized alkaline-soluble resin (A-1) and 15 g of a photosensitive diazoquinone compound having a structure of the following formula (B-1) was dissolved in 150 g of γ-butyrolactone, and then was filtered with a filter made of Teflon™ with pore diameter of 0.2 μm to obtain the positive type photosensitive polymer composition.

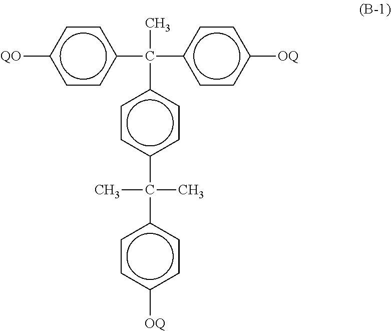

In formula, Q represents atomic hydrogen or

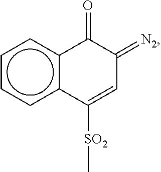

wherein 70% of the whole Q is

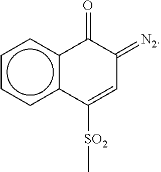

### Evaluation of Surface Condition of Coating Film after Developing and Rinsing

A silicon wafer (8 inches) was coated with the above-described positive type photosensitive polymer composition by employing a spin coater, and then a pre-baking process was conducted with a hot plate at 120 degrees C. for 4 minutes to obtain a coating film having a thickness of about 8.0 μm. Such coating film was irradiated with a chemical ray through a mask (commercially available from Toppan Printing Co., Ltd., Test chart No. 1: containing negative pattern and positive pattern having widths of 0.88 to 50 μm) by employing an i-ray stepper (commercially available from Nikon: NSR-4425i) under the condition of the increasing irradiation levels from 100 mJ/cm² to 780 mJ/cm² by an increment of 10 mJ/cm². In the next, the silicon wafer having the coated and irradiated positive type photosensitive polymer composition was rotated at a circumferential velocity of 0.53 m/s while a developer solution of 2.38% tetramethylammonium hydroxide (aqueous solution of 2.38% tetramethylammonium hydroxide) was discharged from a developer solution nozzle disposed in the center section of the silicon wafer, and the developer solution nozzle was moved toward the circumference of the silicon wafer during this process, and finally the move of the developer solution nozzle was stopped when the nozzle was situated around the circumference of the silicon wafer. The circumferential velocity of the silicon wafer was gradually decreased as the developer solution nozzle was moved, and was eventually decreased to 0.21 m/s, the rotation of the silicon wafer was stopped at the same time the developer solution nozzle was stopped, and then the wafer was allowed to stand for 50 seconds. At this time, the alkaline developer solution was preset in the form of liquid on the coating film of the silicon wafer. In the next, the silicon wafer was rotated at the circumferential velocity of 7.33 m/s to eliminate the developer solution from the silicon wafer. Then, the developer solution of 2.38% tetramethylammonium hydroxide (aqueous solution of 2.38% tetramethylammonium hydroxide) was discharged from a developer solution nozzle disposed in the center section of the silicon wafer while the silicon wafer was rotated at a circumferential velocity of 7.33 m/s, and the developer solution nozzle was moved toward the vicinity of the circumference of the silicon wafer during this process, and finally the move of the developer solution nozzle was stopped when the nozzle was situated around the circumference of the silicon wafer. The circumferential velocity of the silicon wafer was gradually decreased as the developer solution nozzle was moved, and was eventually decreased to 0.21 m/s, the rotation of the aforementioned wafer was stopped at the same time the developer solution nozzle was stopped, and then the wafer was allowed to stand for 50 seconds. At this time, the alkaline developer solution was preset in the form of liquid on the coating film of the silicon wafer. Next, while the silicon wafer was rotated at the circumferential velocity of 0.31 m/s, the pure water serving as a rinsing solution was supplied in the center section of the silicon wafer for 5 seconds (1 L/min, first rinsing step), and then, Then, the rotating speed of the silicon wafer was increased, and while the silicon wafer was rotated at the circumferential velocity 12.57 m/s, the pure water was supplied in the center section of the silicon wafer for 10 seconds (1 L/min, second rinsing step) to carry out the rinsing. In addition to above, in the first rinsing step, the supply of the pure water was started simultaneously with starting the rotation of the silicon wafer. Further, the pure water was also continuously supplied after the first rinsing step was finished and before the circumferential velocity of the silicon wafer was reached to 12.57 m/s. No residual substance was observed in the openings of the coating film after the rinsing. The evaluation results for the residual substance were represented as follows.
“A”: There was no residual substance in openings after developing and rinsing for entire coating film.
“B”: There were extremely slightly amount of residual substances in some of the openings in the substantially circumference section of the coating film
(level of causing no problem on the practical use).
“C”: There were residual substances in the openings of the entire substantially circumference section of the coating film.
“D”: There were residual substances in the opening of the entire coating film.

### Example 2

The developing and the rinsing processes were carried out similarly as in Example 1 except that the first rinsing step was conducted at the circumferential velocity of 0.31 m/s for 10 seconds, and the evaluation for the surface condition of the resultant coating film was conducted. No residual substance was observed in the opening of the coating film after the rinsing process.

### Example 3

The developing and the rinsing processes were carried out similarly as in Example 1 except that the first rinsing step was conducted at the circumferential velocity of 0.31 m/s for 1 second, and the evaluation for the surface condition of the resultant coating film was conducted. No residual substance was observed in the opening of the coating film after the rinsing process.

### Example 4

The developing and the rinsing processes were carried out similarly as in Example 1 except that the first rinsing step was conducted at the circumferential velocity of 0.42 m/s for 5 seconds, and the evaluation for the surface condition of the resultant coating film was conducted. No residual substance was observed in the opening of the coating film after the rinsing process.

### Example 5

The developing and the rinsing processes were carried out similarly as in Example 1 except that the first rinsing step was conducted at the circumferential velocity of 0.42 m/s for 10 seconds, and the evaluation for the surface condition of the resultant coating film was conducted. No residual substance was observed in the opening of the coating film after the rinsing process.

### Example 6

The developing and the rinsing processes were carried out similarly as in Example 1 except that the second rinsing step was conducted at the circumferential velocity of 12.57 m/s for 20 seconds, and the evaluation for the surface condition of the resultant coating film was conducted. No residual substance was observed in the opening of the coating film after the rinsing process.

### Example 7

The developing and the rinsing processes were carried out similarly as in Example 1 except that the second rinsing step was conducted at the circumferential velocity of 3.14 m/s, and the evaluation for the surface condition of the resultant coating film was conducted. No residual substance was observed in the opening of the coating film after the rinsing process.

### Example 8

The developing and the rinsing processes were carried out similarly as in Example 1 except that the second rinsing step was conducted at the circumferential velocity of 26.18 m/s, and the evaluation for the surface condition of the resultant coating film was conducted. No residual substance was observed in the opening of the coating film after the rinsing process.

### Example 9

The developing and the rinsing processes were carried out similarly as in Example 1 except that the first rinsing step was conducted at the circumferential velocity of 0.21 m/s for 5 seconds, and the evaluation for the surface condition of the resultant coating film was conducted. No residual substance was observed in the opening of the coating film after the rinsing process.

### Example 10

The developing and the rinsing processes were carried cut similarly as in Example 1 except that the second rinsing step was conducted at the circumferential velocity of 38 m/s for 10 seconds, and the evaluation for the surface condition of the resultant coating film was conducted. No residual substance was observed in the opening of the coating film after the rinsing process.

### Example 11

The developing and the rinsing processes were carried out similarly as in Example 1 except that the flow rates of the rinsing solution in the first rinsing step the second rinsing step were 0.8 L/min, and the evaluation for the surface condition of the resultant coating film was conducted. No residual substance was observed in the opening of the coating film after the rinsing process (Evaluation result “A”).

### Example 12

The developing and the rinsing processes were carried out similarly as in Example 1 except that the flow rates of the rinsing solution in the first rinsing step the second rinsing step were 1.2 L/min, and the evaluation for the surface condition of the resultant coating film was conducted. No residual substance was observed in the opening of the coating film after the rinsing process (Evaluation result “A”).

### Example 13

The developing and the rinsing processes were carried out similarly as in Example 1 except that a photosensitizing agent used in Example 1 (B-1) was changed to another type of photosensitizing agent (B-2), and the evaluation for the surface condition of the resultant coating film was conducted. No residual substance was observed in the opening of the coating film after the rinsing process (Evaluation result “A”). In the synthesis of the photosensitizing agent (B-2), 15.82 g (0.025 mol) of phenol (formula Q-2) was introduced into a four-necked separable flask equipped with a thermometer, a stirrer a raw materials-supply port, and a dried nitrogen gas supply tube, and 135 g of tetrahydrofuran was added thereto to be dissolved. Such reaction solution was cooled to equal to or lower than 10 degrees C., and then 22.30 g (0.083 mol) of 1,2-naphthoquinone-2-diazide-4-sulfonyl chloride was gradually dropped with 100 g of tetrahydrofuran so as to preventing the temperature from being increased to equal to or higher than 10 degrees C. Thereafter, it was stirred for 5 minutes at equal to or lower than 10 degrees C., and then, was stirred at a room temperature for 5 hours to complete the reaction. The reaction mixture was filtered out, and then, the obtained reaction mixture was supplied to a solution of water/methanol=3/1 (volumetric ratio), and the precipitates was filtered out, and sufficiently rinsed with water, and then was dried under the vacuum atmosphere to obtain the photosensitive diazoquinone compound represented by the structure of formula (B-2).

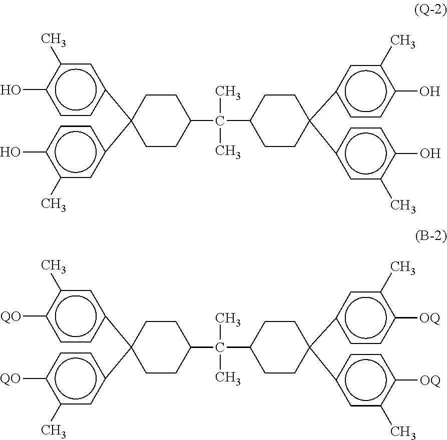

In formula, Q represents atomic hydrogen or

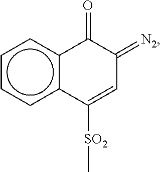

wherein 83% of the whole Q is

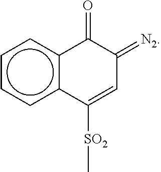

### Comparative Example 1

The developing and the rinsing processes were carried out similarly as in Example 1 except that the first rinsing step was no conducted, and the evaluation for the surface condition of the resultant coating film was conducted. The residual substances were observed in the openings of the coating film after the rinsing process (Evaluation result “D”).

### Comparative Example 2

The developing and the rinsing processes were carried out similarly as in Example 1 except that the first rinsing step was conducted at the circumferential velocity of 0.63 m/s for 5 seconds, and the evaluation for the surface condition of the resultant coating film was conducted. The residual substances were observed in the openings of the coating film after the rinsing process (Evaluation result “D”).

### Comparative Example 3

The developing and the rinsing processes were carried out similarly as in Example 1 except that the first rinsing step was conducted at the circumferential velocity of 0.63 m/s for 10 seconds, and the evaluation for the surface condition of the resultant coating film was conducted. The residual substances were observed in the openings of the coating film after the rinsing process (Evaluation result “C”).

### Comparative Example 4

The developing and the rinsing processes were carried out similarly as in Example 1 except that the first rinsing step was conducted at the circumferential velocity of 1.05 m/s for 5 seconds, and the evaluation for the surface condition of the resultant coating film was conducted. The residual substances were observed in the openings of the coating film after the rinsing process (Evaluation result “D”).

TABLE 1

| | | EXAMPLES | | | | | | | |
|---|---|---|---|---|---|---|---|---|---|
| | | 1 | 2 | 3 | 4 | 5 | 6 | 7 | 8 |
| FIRST | CIRCUMFERENTIAL | 0.31 | 0.31 | 0.31 | 0.42 | 0.42 | 0.31 | 0.31 | 0.31 |
| RINSING | VELOCITY [m/s] | | | | | | | | |
| STEP | TIME [s] | 5 | 10 | 1 | 5 | 10 | 5 | 5 | 5 |
| SECOND | CIRCUMFERENTIAL | 12.57 | 12.57 | 12.57 | 12.57 | 12.57 | 12.57 | 3.14 | 26.18 |
| RINSING | VELOCITY [m/s] | | | | | | | | |
| STEP | TIME [s] | 10 | 10 | 10 | 10 | 10 | 20 | 10 | 10 |

| | | | | | | | | |
|---|---|---|---|---|---|---|---|---|
| FLOW RATE OF RINSING | 1 | 1 | 1 | 1 | 1 | 1 | 1 | 1 |
| SOLUTION IN RINSING STEP | | | | | | | | |
| [L/min] | | | | | | | | |
| RESIDUES IN OPENING | A | A | A | B | A | A | A | A |

TABLE 2

| | | | | | | | COMPARATIVE | | | |
|---|---|---|---|---|---|---|---|---|---|---|
| | | EXAMPLES | | | | | EXAMPLES | | | |
| | | 9 | 10 | 11 | 12 | 13 | 1 | 2 | 3 | 4 |
| FIRST | CIRCUMFERENTIAL | 0.21 | 0.31 | 0.31 | 0.31 | 0.31 | — | 0.63 | 0.63 | 1.05 |
| RINSING | VELOCITY [m/s] | | | | | | | | | |
| STEP | TIME [s] | 5 | 5 | 5 | 5 | 5 | — | 5 | 10 | 5 |
| SECOND | CIRCUMFERENTIAL | 12.57 | 38 | 12.57 | 12.57 | 12.57 | 12.57 | 12.57 | 12.57 | 12.57 |
| RINSING | VELOCITY [m/s] | | | | | | | | | |
| STEP | TIME [s] | 10 | 10 | 10 | 10 | 10 | 10 | 10 | 10 | 10 |

| | | | | | | | | | |
|---|---|---|---|---|---|---|---|---|---|
| FLOW RATE OF RINSING | 1 | 1 | 0.8 | 1.2 | 1 | 1 | 1 | 1 | 1 |
| SOLUTION IN RINSING STEP | | | | | | | | | |
| [L/min] | | | | | | | | | |
| RESIDUES IN OPENING | A | A | A | A | A | D | D | C | D |

It can be seen that there was substantially no residual substance in the openings in each of Examples 1 to 13. On the contrary, it was found as shown in Comparative Example 1 that the residual substances were generated when the support was rotated in the rinsing step at a higher rotating velocity as in the conventional technology. Further, it was found as shown in Comparative Examples 2 to 4 that the residual substances were generated when the circumferential velocity in the first rinsing step was larger than 0.53 m/s.

### INDUSTRIAL APPLICABILITY

The method or forming the cured film composed of the positive type photosensitive polymer composition according to the present invention provides a method for forming the cured film of the positive type photosensitive polymer composition, which is capable of providing a formation of a pattern without generating a residual substance in the opening with enhanced resolution.

1. A method for forming a cured film of a positive type photosensitive polymer composition over a support, including:
a coating step for coating said support with said positive type photosensitive polymer composition;
an exposure step for selectively irradiating said positive type photosensitive polymer composition with a chemical ray to achieve an exposure;
a developing step for developing an exposed section of said positive type photosensitive polymer composition with an alkaline developer solution;
a rinsing process for rinsing said developer solution off with a rinsing solution and removing the exposed section of said positive type photosensitive polymer composition; and
a curing step for heating said positive type photosensitive polymer composition to form a cured film,
wherein said rinsing step includes a first rinsing step and a second rinsing step, said first rinsing step including supplying a rinsing solution while said support is rotated at a circumferential velocity of equal to or lower than 0.53 m/s or while said support is maintained in the resting state, and said second rinsing step including supplying the rinsing solution while said support is rotated at a circumferential velocity that is higher than the circumferential velocity of said first rinsing step.

2. The method for forming the cured film of the positive type photosensitive polymer composition according to claim 1, wherein the circumferential velocity of said support in the second rinsing step is within a range of from 3 to 40 m/s.

3. The method for forming the cured film of the positive type photosensitive polymer composition according to claim 1, wherein said first rinsing step is conducted for equal to or longer than one second.

4. The method for forming the cured film of the positive type photosensitive polymer composition according to claim 1, wherein said developing step includes conducting a puddle developing process to form a film of said alkaline developer solution over said positive type photosensitive polymer composition.

5. The method for forming the cured film of the positive type photosensitive polymer composition according to claim 1, wherein said positive type photosensitive polymer composition contains:
a resin (A) at least one selected from: a resin having at least one of polybenzoxazole structure and polyimide structure and having hydroxyl group, carboxylic group, ether group or ester group in a main chain or a side chain; a resin having polybenzoxazole precursor structure; a resin having polyimide precursor structure; and a resin having polyamic acid ester structure; and
a photosensitive diazoquinone compound (B).

6. The method for forming the cured film of the positive type photosensitive polymer composition according to claim 1, wherein a viscosity of said alkaline developer solution at 25 degrees C. is equal to or higher than 0.8 mPa·s and equal to or lower than 3.0 mPa·s.
